(19) United States
(12) Patent Application Publication
(10) Pub. No.: US 2022/0037544 A1
(43) Pub. Date: Feb. 3, 2022

(54) MULTIBANDGAP NANOCRYSTAL ENSEMBLES FOR SOLAR-MATCHED ENERGY HARVESTING

(71) Applicant: QD SOLAR INC., Toronto (CA)

(72) Inventors: Bin SUN, Toronto (CA); Olivier OUELETTE, Chute-Saint-Philippe (CA); F. Pelayo GARCIA DE ARQUER, Toronto (CA); Sjoerd HOOGLAND, Toronto (CA); Edward H. SARGENT, Toronto (CA)

(21) Appl. No.: 17/274,975

(22) PCT Filed: Sep. 10, 2019
(86) PCT No.: PCT/CA2019/051269

§ 371 Date: Mar. 10, 2021

Related U.S. Application Data
(60) Provisional application No. 62/728,912, filed on Sep. 10, 2018.

(51) Int. Cl. H01L 31/0352; H01L 31/072

(52) U.S. Cl. CPC H01L 31/035218; H01L 31/072

(57) ABSTRACT

Disclosed is a quantum dot based solar cell device which includes a substrate, a light harvesting structure sandwiched between electrically conducing layers, with at least one electrically conducting layer being substantially transparent with the light harvesting structure being located on the substrate. The light harvesting structure includes a layer of semiconducting quantum dots, with this layer of semiconducting quantum dots including at least two distinct sets of semiconducting quantum dots which are homogenously mixed. One of the two distinct sets of semiconducting quantum dots has a first bandgap and the at least one other distinct set of semiconducting quantum dots has a second bandgap different from the first bandgap. Both sets of semiconducting quantum dots are passivated with any one or combination of halides and pseudo-halides. Upon illumination, the quantum dot solar cell device exhibits a photovoltage that is intermediate between a photovoltage that would generated separately if the solar cell device had only the first set of quantum dots and a photovoltage that would be generated separately if the solar cell device had only the second set of quantum dots.

### FIELD

The present application concerns the technical field of thin-film photovoltaics and optoelectronic devices, and particularly to quantum dot nanocrystal films and solar cell devices.

### BACKGROUND

Photovoltaics accounted for 1.3% of the global energy supply in 2016, a number that is projected to increase to 20% by 2050. As crystalline silicon (cSi) solar cells approach their theoretical efficiency limit, complementary strategies that further improve efficiency—without introducing significant additional cost—provide avenues to lower further the price of solar electricity.

With an indirect bandgap of 1.1 eV corresponding to an absorption edge at 1100 nm, Si solar cells leave up to 20% of the solar power reaching the Earth's surface unabsorbed. Efficient infrared energy harvesting that could complement Si absorption is a promising route to achieve broadband solar energy conversion, which is predicted to offer up to 6% additional power points on top of existing cSi photovoltaic solutions.

Colloidal quantum dots (CQDs) combine facile and broad spectral tunability via quantum-size tuning with inexpensive manufacturing arising from their solution-processing. In the last decade, intensive efforts have focused on improving CQD synthesis, surface passivation, film formation, and device engineering; and these have led to great strides in increasing the performance of CQD photovoltaics. IR CQD solar cells, on the other hand, have remained comparatively underexplored, and best IR-filtered PCEs lie below 0.5%.

An acute challenge in CQD solar cells is to realize simultaneously high short-circuit current (J_{SC}) and high open-circuit voltage (V_{OC}). As the size of QDs is increased and their bandgap shrinks so that more IR photons can be absorbed—a crucial step to harvest the solar power beyond 1100 nm—V_{OC} decreases due to the smaller bandgap and the presence of energy losses (Eₗₒₛₛ). Eₗₒₛₛ is defined as the deficit in V_{OC} compared to the detailed balance limit for V_{OC} at a given bandgap, and in CQD photovoltaics it stems primarily from bandtail states and recombination at defects. While energy losses on the order of 0.1 eV to 0.2 eV are observed for highly crystalline and low-defect materials such as cSi, CQDs are characterized by significantly higher values, reaching 0.4 eV. The reduction of bandtail states to decrease this detrimental loss has therefore been a widespread theme in recent work. The absorption/extraction compromise, which limits the thickness of the CQD active layer to a few hundreds of nanometers, represents an additional impediment to harvesting fully the infrared portion of the solar spectrum. Harvesting the full solar spectrum efficiently remains an unresolved challenge.

### SUMMARY

The present disclosure provides a quantum dot based solar cell device, comprising:

a substrate;

a light harvesting structure sandwiched between electrically conducting layers, at least one electrically conducting layer being substantially transparent, said light harvesting structure being located on said substrate;

said light harvesting structure including a layer of semiconducting quantum dots, said layer of semiconducting quantum dots including at least two distinct sets of semiconducting quantum dots which are homogenously mixed, one of said two distinct sets of semiconducting quantum dots having a first bandgap and the at least one other distinct set of semiconducting quantum dots having a second bandgap different from said first bandgap, both sets of semiconducting quantum dots being passivated with any one or combination of halides and pseudo-halides; and upon illumination, said quantum dot solar cell device exhibits a photovoltage that is intermediate between a photovoltage that would generated separately if said solar cell device had only the first set of quantum dots and a photovoltage that would be generated separately if said solar cell device had only the second set of quantum dots.

The offset of both the valence and conduction bands in the at least two different types of quantum dots have an offset by amounts being up to about 0.3 eV and the bandgap difference between the smallest bandgap value and the largest bandgap value in the quantum dot sets has an offset up to about 0.3 eV.

The at least two distinct sets of semiconducting quantum dots may have the same chemical composition, but have different sizes such that each distinct set has a bandgap different from the other set.

Alternatively, in the solar cell device each set of semiconducting quantum dots may have a chemical composition different from the other sets.

An interparticle separation of quantum dots in the homogenous mixture may be in a range from about 0.1 nm to about 1 nm.

The first set of quantum dots may be present in the homogenous mixture in a range of about 1 to about 99 weight percent.

The semiconducting quantum dots may be any one of Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS), InAs, InₓGa_{y}As_{z}, Ag₂S, Ag₂Se, ZnSe, SnS₂, and core-shell structures based on these quantum dots as the core.

The halide may be any one or combination of chloride, bromide and iodide.

The pseudo halide may be any one or combination of cyanide, cyanate, thiocyanate, isothiocyanate, selenocyanate and trinitromethanide.

The solar cell device may further include a hole transport layer sandwiched between the layer of semiconducting quantum dots and one of the electrodes on one side of the layer of semiconducting quantum dots and an electron transport layer semiconducting sandwiched between the layer of semiconducting quantum dots and the other electrode on the other side of the layer of semiconducting quantum dots. A further understanding of the functional and advantageous aspects of the invention can be realized by reference to the following detailed description and drawings.

### BRIEF DESCRIPTION OF THE DRAWINGS

Embodiments disclosed herein will be more fully understood from the following detailed description thereof taken in connection with the accompanying drawings, which form a part of this application, and in which:

FIGS. 1A to 1C shows open-circuit modulation in multi-bandgap QD ensembles under illumination, in which:

FIG. 1A shows a single population of small bandgap colloidal quantum dots (CQDs),

FIG. 1B shows overlap of the Fermi-Dirac occupation function at the quasi-Fermi level ƒ(E,E_{QFL}) and the density of states (DOS) at the CQD conduction g_{CB}(E) band, and

FIG. 1C shows V_{OC} behavior upon CQD mixing depending on the energy offset of the large bandgap inclusions in the mixed CQD films.

FIGS. 2A and 2B show the transient absorption spectra of pure CQD films. Bottom left of each of FIGS. 2A and 2B show the 2D spectrum. The top left of each of FIGS. 2A and 2B shows the temporal cross-section. The right side of each of FIGS. 2A and 2B show the spectral cross-section, with:

FIG. 2A showing the pure small bandgap CQD film, photoexcitation at 1300 nm, and

FIG. 2B show the pure large bandgap CQD film, photoexcitation at 1160 nm. The 1300 nm photoexcitation wavelength was chosen to minimize the partial excitation of the small-bandgap population in the mixed CQD sample (FIGS. 3A and 3B) and was used for the single-size sample for consistency. When studying the pure-phase small-gap film as a control, the absorption change at the wavelength corresponding to the large-gap-phase's excitonic feature is at least 20 times lower than the absorption change at the wavelength corresponding to the small-gap-phase's excitonic feature; conversely, when studying the pure-phase large-gap film as control, the absorption change at the wavelength corresponding to the small-gap-phase's excitonic feature is about 5 times lower than the absorption change at the wavelength corresponding to the large-gap-phase's excitonic feature.

FIGS. 3A and 3B show transient absorption spectra of L/S 2/1 mixed CQD films. The bottom left of FIGS. 3A and 3B show the 2D spectrum, the top left shows the temporal cross-section. The right side of each of FIGS. 3A and 3B show the spectral cross-section, with:

FIG. 3A showing photoexcitation mainly in the small bandgap population at 1300 nm. Although we directly photoexcited very selectively only the small-gap phase (see FIG. 2A), the bleach at 1170 nm—characteristic of the large-gap phase—is within a factor of two of the bleach at 1265 nm. We conclude that charge carriers are able to transfer mildly-uphill from their place of creation (small-gap phase) into the larger-gap phase, and

FIG. 3B shows photoexcitation mainly in the large bandgap population at 1160 nm; the absorption cross-section is approximately 13 times greater in the large-bandgap QDs than in the small-bandgap QDs for the case of 1160 nm photoexcitation. Charge transfer from the photoexcited population to the other is observed in both cases, confirming that thermalization happens before most recombination. Exponential fits to the temporal cross-sections reveal transfer times of 90 picoseconds (ps) from large-bandgap to small-bandgap dots and 175 ps from small-bandgap to large-bandgap dots.

FIGS. 4A to 4D shows the optimization of ligand exchange for large bandgap CQDs. The optimized ammonium acetate (AA) concentration in the precursor solution is 20 mM in DMF. When the AA concentration is lower than 20 mM, fill factor (FF) and short circuit current density (J_{SC}) decrease, which is attributed to the high amount of organic ligand on the surface, resulting in worse charge transport. When increasing the AA concentration, surface passivation gets worse, resulting in decreased PV performance, particularly lowering open circuit voltage (V_{OC}) and FF as shown in FIGS. 4A and 4B.

FIGS. 5A to 5C show butylamine (BTA) assisted ligand exchange on small bandgap dots, in which:

FIGS. 5A and 5B show device performance as a function of AA and BTA concentration: V_{OC} increases with increasing BTA concentration and decreases with increasing AA fraction; the highest PCE (0.62%) is obtained when AA (60 mM) and BTA (40 mM) are added, which is higher than the previously reported PCE of solution exchanged 1250 nm PbS CQDs, and

FIG. 5C shows x-ray photoelectron spectroscopy (XPS) elemental ratios reveal the higher ratio of I:S and C:S measured by x-ray photoelectron spectroscopy, when using BTA (40 mM in precursor solution) compared to the control ligand exchange without BTA, showing that the addition of BTA keeps more iodide and organics (Oleic acid) on the CQD surface for better surface passivation.

FIGS. 6A to 6D shows transport properties of CQD multi-bandgap ensembles in which:

FIG. 6A shows a bottom-gate top-contact field-effect transistor structure; transfer characteristics of pure CQD and multi-bandgap CQD ensembles with different weight ratio of large bandgap (L) to small bandgap (S) CQDs showing onset voltage (V_{ON}),

FIG. 6B shows transfer characteristics of pure and mixed CQDs with different weight ratios of large bandgap (L) to small bandgap (S),

FIG. 6C shows the tail state density (N_{T}) of the optimal CQD mixture (weight ratio of 2 to 1) as a function of gate bias as calculated with Equation:

$${N}_{t d} = {[ ( \frac{S \cdot e}{kT \cdot ln ( 10 )} - 1 ) \cdot \frac{{C}_{i}}{e} ]}^{2} \cdot {ϵ}_{0} {ϵ}_{r}^{- 1} \qquad ( 1 )$$

and

FIG. 6D shows the mobility and trap density as a function of the inclusion of L in the mixed films.

FIG. 7A to 7D shows trap density extracted from FET devices, in which:

FIG. 7A is for single large bandgap CQDs,

FIG. 7B is for single small bandgap CQDs,

FIG. 7C mixes with 50% of large bandgap CQDs, and

FIG. 7D mixes with 33% of large bandgap CQDs.

FIG. 8 shows the transport properties of small bandgap dots exchanged with and without BTA to assist exchange. Exchange was done using 60 mM of AA and 40 mM of BTA (if used). Black circles denote the carrier mobility in CQDs. The absence of BTA leads to an electron mobility in the CQD films of 0.0044 cm⁻²s⁻¹V⁻¹, which is one order of magnitude lower than with BTA. The lower mobility is attributed to the surface trap density marked with grey square, which was calculated to be 5.2×10¹⁶ cm⁻³, while BTA-assisted films has a much lower surface trap density of 2.6×10¹⁴ cm⁻³, in good agreement with the PV device performance shown in FIG. 5.

FIG. 9 shows the energy levels of CQD films from ultraviolet photoelectron spectroscopy (UPS). UPS spectra of L, S, and 2-to-1 mixed dots (left) and energy levels (Fermi level (E_{F}) and valence band (VB)) calculated from UPS spectra. A helium discharge source (Hel α, hv=21.22 eV) was used and the samples were kept at a take-off angle of 88°. During measurement, the sample was held at a −15 V bias relative to the spectrometer in order to efficiently collect low kinetic-energy electrons. E_{F} was calculated from the equation: E_{F}=21.22 eV−SEC, where SEC is the secondary electron cut-off. The difference between valence band (VB) and Fermi level, η, was determined from the VB onset in the VB region. The 1150 and 1250 nm CQDs show very similar E_{F} and VB maxima, matching well with the energy alignment for charge transport between different size CQDs. The conduction band (CB) is extracted from the absorption spectra using the position of the first exciton peak.

FIGS. 10A to 10D shows resonant enhanced light absorption. Absorptance measured from double pass (solid line, with gold electrode mirror) and single pass (dashed line, without gold electrode mirror) of solar cells with different CQD active layer thicknesses, in which:

FIG. 10A shows this for small bandgap CQD film,

FIG. 10B shows this for large bandgap film,

FIG. 10C shows this for a mixture containing 67% of large bandgap CQDs, and

FIG. 10D is for a ratio of double pass over single pass absorption at the position of the highest exciton peak; the ratio increases with thickness from 180 nm to 300 nm, then decreases when the thickness is further increased.

FIGS. 11A to 11C show expected J_{SC} from multi-bandgap CQD ensembles with absorptance measured from:

FIG. 11A the CQD films on glass,

FIG. 11B complete solar cell devices including the gold electrode mirror; and

FIG. 11C calculated J_{SC} as a function of CQD film thickness.

FIGS. 12A to 12C show a PV device architecture and performance in which:

FIG. 12A shows the device architecture and cross-sectional SEM image of the best mixed CQD film solar cell.

FIG. 12B shows the measured V_{OC},

FIG. 12C shows PCE with the different inclusion of large bandgap CQDs

FIG. 12D shows the J-V characteristics under AM1.5G,

FIG. 12E shows the J-V characteristics after 1100 nm, and

FIG. 12F shows the AM1.5G EQE curves and IQE curves of optimal single and mixed CQD solar cell devices.

FIG. 13 shows the available J_{SC} in thick active layers, illustrating the role of optical resonance in enhancing light absorption.

FIG. 14 shows the energy loss dependence on the inclusion of large bandgap CQDs in mixed CQD films under full AM1.5G irradiation. The large bandgap CQDs have the largest Eₗₒₛₛ of 0.33 eV, while the small bandgap CQDs show an Eₗₒₛₛ 0.30 eV. After mixing, the 2-to-1 and 1-to-1 mixed CQD films both show an Eₗₒₛₛ of 0.26 eV, and the 1-to-2 mixed CQD film has slightly higher Eₗₒₛₛ of 0.27 eV, all of which are much lower than single CQD films.

FIG. 15 shows V_{OC} change versus inclusion of large gap CQDs in mixtures of 1150 nm and 1512 nm. The V_{OC} of mixtures is close to that of the low bandgap CQDs, when the bandgap difference is 0.26 eV. This fast decrease is in good agreement with the theoretical model.

FIG. 16 shows the J-V characteristics of single size CQDs and mixes under AM1.5G.

FIGS. 17A to 17C show EQE curves and expected J_{SC} integrated under AM1.5G irradiation, in which EQE curves are shown as follows:

FIG. 17A without the 1100 nm long pass filter,

FIG. 17B through an 1100 nm long-pass filter, and

FIG. 17C transmittance of the 1100 nm long-pass filter used in this work.

FIG. 18 shows the impact of exciton peak width showing the full width at half max (FWHM) (FIG. 18B) extracted from the absorption spectrum of single size CQDs and mixes (FIG. 18A). The mixed CQD films exhibit a larger FWHM, which contributes to their higher J_{SC} and PCE.

FIGS. 19A to 19D show thickness dependence of the IR PV performance, in which:

FIG. 19A, 19B, 19C, 19D shows the V_{OC}, J_{SC}, FF and IR PCE for large bandgap film, small bandgap CQD film, mixture containing 67%, 50%, and 33% of large bandgap CQDs, respectively.

FIG. 20 shows the solar simulator lamp spectrum, with and without 1100 nm long-pass filter, with the AM1.5G standard spectrum for comparison.

FIG. 21 shows the dark diode analysis of best PV device with different inclusion of large bandgap CQDs, in which:

FIG. 21A shows dark IV and FIG. 21B extracted ideality factor from dark IV (FIG. 21A). In the quasi-flat region, the ideality factor of small bandgap CQDs and mixed films is slightly lower than that of the large bandgap CQD films. This is an indication of a higher density of trap states in large bandgap CQDs, in good agreement with the FET data. The ideality factor increasing above 2 at higher voltages is due to series resistance.

FIG. 22 shows the absorption coefficient of the CQD films used to calculate G, obtained from spectroscopic ellipsometry.

FIGS. 23A and 23B show the effect of trap density on the V_{OC} model, in which:

FIG. 23A shows a calculation done with two different trap densities, illustrating how the V_{OC} pinning trend from FIG. 1c is not affected, and

FIG. 23B shows the V_{OC} limit in the large ΔE case for different trap densities in absolute units, showing that only the magnitude of V_{OC} is changed.

FIG. 24 shows a vertical side view of a layered solar cell.

### DETAILED DESCRIPTION

Without limitation, the majority of the systems described herein are directed to multibandgap nanocrystal ensembles for solar-matched energy harvesting. As required, embodiments of the present invention are disclosed herein. However, the disclosed embodiments are merely exemplary, and it should be understood that the invention may be embodied in many various and alternative forms.

The accompanying figures, which are not necessarily drawn to scale, and which are incorporated into and form a part of the instant specification, illustrate several aspects and embodiments of the present disclosure and, together with the description therein, serve to explain the principles of the process of producing multibandgap nanocrystal ensembles for solar-matched energy harvesting. The drawings are provided only for the purpose of illustrating select embodiments of the apparatus and as an aid to understanding and are not to be construed as a definition of the limits of the present disclosure. For purposes of teaching and not limitation, the illustrated embodiments are directed to multibandgap nanocrystal ensembles for solar-matched energy harvesting.

As used herein, the terms, “comprises” and “comprising” are to be construed as being inclusive and open ended, and not exclusive. Specifically, when used in the specification and claims, the terms, “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately”, when used in conjunction with ranges of dimensions of particles, compositions of mixtures or other physical properties or characteristics, are meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present disclosure.

As used herein, the phrase quantum dots refers to semiconducting particles that have the size below the Exciton Bohr radius. Quantum dot bandgaps may range from about 0.5 electron Volts (eV) to about 3 eV, and may include but are not limited to, PbS, PbSe, Ag₂S, Ag₂Se, Bi₂S₃, ZnSe, SnS₂, CdS, CdSe to mention just a few. As used herein, the phrase “interparticle separation” refers to the shortest distance from the surface of one quantum dot to that of the adjacent quantum dot.

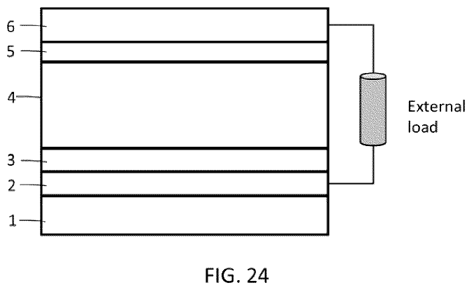

FIG. 24 shows a solar cell device comprised of a substrate 1 and a light harvesting structure 4 sandwiched between electrically conducting electrodes located on substrate 1. The sandwich structure comprises two electrodes 2 and 6, either or both of which are transparent, and one of 3 and 5 is electron transport layer and the other one is hole transport layer. The electron and hole transport layers sandwich the light harvesting structure 4 which is comprised of at least two sets of quantum dots. When under illumination the photogenerated carriers are routed through an external load that is electrically connected to the electrodes 2 and 6. There is no particular order of the layers on substrate 1, however, if the transparent electrode is on and adjacent to the substrate surface then the substrate 1 needs to be substantially transparent so that light enters the quantum dot layer 4 through the substrate and the generally transparent electrode layer. Alternatively if the ordering of the layers is such that the transparent electrode layer is not on the substrate 1 but at the other side of the layered stack, then the solar cell is positioned such that the light enters the quantum dot layer 4 through the transparent layer so that the substrate does not have to be transparent. In the event it is desired to illuminate the quantum dot layer 4 through both electrodes 2 and 6 then both of these electrodes and the substrate 1 will be transparent. The hole and electron transport layers (ETL, HTL) are very thin and hence will be at least partially transparent.

The layer of quantum dots is sandwiched between a hole transport layer (also referred to as an electron blocking layer) and a hole blocking layer (also known as an electron blocking layer). The electron blocking layer has a typical thickness from 5 to 1000 nm; the hole blocking layer has a typical thickness from about 5 to about 1000 nm; the nanocomposite layer may have a thickness in a range from about 50 to about 3000 nm.

The photovoltaic devices or solar cells compromise different size QDs, wherein any single QD is present in a weight percentage of 1 to 99%. A photovoltaic nanocomposite may compromise different size QDs, such as for example QD semiconductors comprising as Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS); InAs, InₓGa_{y}As_{z}, Ag₂S, Ag₂Se; and core-shell structures based on these QDs as the core.

These photovoltaic nanocomposites are comprised of a mixture of solution-processed semiconductor materials with different bandgaps such as QDs of different sizes or semiconductor nanocrystal of different materials. These are synthesized first separately followed by ligand exchange to remove long organic ligands and replace them with any one or combination of pseudo-halides or halides thereby passivating the surfaces. Passivating with these halides or pseudo halides allows the interparticle separation to be reduced to be in the range from about 0.1 nm to about 1 nm in the homogeneous blend. Once passivated they are then homogeneously blended in a single colloid. At least two populations with different bandgaps are included in the homogeneous blend, but there may be more.

In the light harvesting structure which includes the layer of quantum dots 4, there are at least two (2) distinct sets of quantum dots which are homogenously mixed, one of the two distinct sets of quantum dots has a first bandgap and the other distinct set of quantum dots has a second bandgap which is different from the first bandgap. Both sets of quantum dots are passivated with any one or combination of halides and pseudo-halides. The light harvesting structure having the homogenous mixture of at least two distinct sets of quantum dots exhibits a photovoltage, upon illumination through the substantially transparent electrically conducing layer, that is intermediate between a voltage that is generated separately if the solar cell device had only the first set of quantum dots and a voltage that is generated separately if the solar cell device had only the second set of quantum dots. The halides may include any one or combination of chloride, bromide and iodide. The pseudo-halides may include cyanide, cyanate, thiocyanate, isothiocyanate, selenocyanate, trinitromethanide to mention a few non-limiting examples.

Passivating the quantum does with one or combination of halides and pseudo-halides while substantially removing the typically present longer organic based ligands allows a closer interparticle separation of adjacent quantum dots. This interparticle separation of quantum dots in THE homogenous mixture is typically in a range from about 0.1 nanometer (nm) to about 1 nm.

While the present disclosure uses as an example two different sizes of lead sulphide (PbS) quantum dots (which will have different bandgaps from each other, it will be appreciated that more than two (2) types of quantum dots could be used. Thus, when referring to two (2) types of quantum dots, it will be appreciated that they may be of different compositions, instead of two differently sized quantum dots of the same semiconductor material, they may be two or more types of different semiconductor quantum dots having particular bandgap values and energy level positions.

The mixture of at least two types of quantum dots with different bandgaps (Eg) very advantageously allows the light harvesting layer of quantum dots 4 to absorb more photons from the solar spectrum. A key feature of the homogenous mixture of quantum dots of at least two different bandgaps is the overlap of the Femi-Dirac distribution of either or both of electrons and holes, which depend on the relative weight of the populations and the energy difference ΔE in both of conduction band and valence band of the mixed quantum dot ensembles. The relative weight of the populations of each type of quantum dots should be from about 1% to about 99%. The energy difference ΔE is limited from about 0.01 eV to about 0.3 eV. In summary, the key features of the mixture of two or more types of quantum dots in the solar cell is to give a voltage under light illumination that is intermediate between that is generated separately if the solar cell device had only the first type of quantum dots and a voltage that is generated separately if the solar cell device had only the second type of quantum dots. Another key feature is the offset of both the valence and conduction bands by amounts being up to about 0.3 eV.

The present disclosure will now be illustrated using the following non-limiting example of a solar cell constructed using two differently sized PbS quantum dots have two different bandgaps.

### Non-Limiting Example

### Methods

### Materials And Characterization

The oleate-capped PbS CQDs and ZnO nanoparticles were synthesized following our previous reports.^{[1]} Other chemicals were obtained from commercial suppliers and used as is. Optical absorption measurements were performed on a Lambda 950500 UV-Vis-IR spectrometer.

### Qds Ligand Exchange and Solution Preparation

The PbI₂/Pb(SCN)₂/AA DMF solution ligand exchange is carried out in a test tube in air. Precursor solution (PbI₂ 0.1 M, AA 0.02 M for 1150 nm CQDs, and PbI₂ 0.1 M, butylamine 0.04 M, and AA 0.06 M for 1250 nm CQDs) is dissolved in DMF. 0.5 ml of oleate-capped PbS CQDs octane solution (50 mg ml⁻¹) was added to 5 ml of precursor solution, followed by vigorously mixing for 2 min until the CQDs completely transferred to the DMF phase. The DMF phase was then washed three times with octane. Then 1150 nm CQDs precipitated during the exchange, while 1250 nm CQDs are stable in DMF and precipitated by adding 4 mL of acetone. The CQD precipitates were collected by centrifugation, followed by vacuum drying for 15 min. The CQDs were redispersed in a mixture of butylamine (BTA) and DMF at a volume ratio of 8/2 (250 mg ml⁻¹) for film by spin coating.

### FET Fabrication

Bottom-gate top-contact FET configuration is used as follows: 70 nm of titanium gate was thermally evaporated onto a glass substrate, followed by 15 nm of ZrO₂ as a dielectric layer using atomic layer deposition (ALD). After 300° C. baking for 1 hour, the pre-exchanged QDs dissolved in BTA/DMF were spin-coated onto the substrate. Then 70 nm of Au source/drain electrodes were thermally deposited using an Angstrom Engineering Amod deposition system. Agilent 4155c semiconductor analyzer was used to characterize the FET devices.

### CQD Solar Cell Fabrication

ZnO layer was adopted as electron acceptor layer and formed on ITO-coated glass substrate by spin coating the ZnO nanoparticles solution at 3000 rpm for 30 s. Then PbS CQDs (pure CQDs or mixtures with different weight ratio), 250 mg mL⁻¹ in BTA/DMF (8/2 volume ratio) solution, were spin cast on ZnO substrate at 2500 RPM for 30 s, followed by two layers of EDT-exchanged PbS CQDs as follows: 2 drops of oleic acid-capped PbS CQDs octane solution (50 mg mL⁻¹) were spin coated at 2500 rpm for 10 s, followed by soaking in 0.01% EDT in acetonitrile (ACN) solution for 30 s and washing with ACN for 3 times. For the top electrode, 120 nm of Au was deposited on EDT PbS CQD film to complete the device.

### External and Internal Quantum Efficiency

EQE and IQE spectra were acquired on a QuantX-300 quantum efficiency measurement system (Newport). Monochromated white light from a xenon lamp was mechanically chopped at a frequency of 25 Hz. EQE spectra were acquired at zero electrical bias, whereas IQE spectra were calculated from an EQE spectra taken at a negative bias of −2 V using the following formula: IQE=EQE(0V)/EQE(−2V).

### Current-Voltage Under Simulated AM1.5

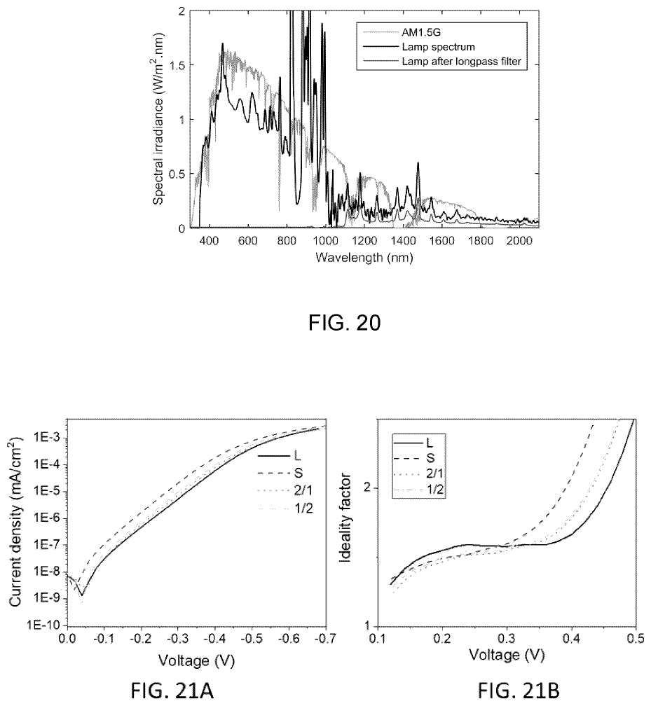

The current-voltage behavior under a simulated AM1.5 solar spectrum was acquired and corrected according to EQE spectra. Devices were kept in an inert N₂ atmosphere. The input power density was adjusted to 1 Sun using a NIST-traceable calibrated reference cell (Newport 91150V). To account for the spectral mismatch between the AM1.5G reference spectrum and the spectrum of the lamp, a current density correction factor was used for each device, corresponding to the ratio of the value calculated from integrating the EQE spectrum and the value measured under illumination. The lamp spectrum was measured using irradiance-calibrated spectrometers (USB2000 and NIR512, Ocean Optics) and is shown in FIG. 20. The calculated spectral mismatch factors are shown in Table 2.

### Ultrafast Transient Absorption Spectroscopy

A regeneratively amplified Yb:KGW laser (PHAROS, Light Conversion) laser was used to generate femtosecond pulses (250 fs FWHM) at 1030 nm as the fundamental beam with a 5 kHz repetition rate. This fundamental beam was passed through a beam-splitter, where one arm was used to pump an optical parametric amplifier (ORPHEUS, Light Conversion) for the narrowband pump, and the other arm was focused into a sapphire crystal (Ultrafast Systems) in order to generate a NIR white-light continuum probe with a spectral window of 1050 nm to 1600 nm. Both arms were directed into a commercial transient absorption spectrometer (Helios, Ultrafast Systems). The probe pulse was delayed relative to the pump pulse to provide a time window of up to 8 ns. All measurements were performed using an average power of 100 ρW with a spot size of 0.40 μm², assuming a Gaussian beam profile.

In this disclosure, the inventors revisit the conditions under which V_{OC} is pinned in CQD ensembles. In doing so, we find a regime wherein V_{OC}—rather than being rapidly pinned by the lowest bandgap component in a quantum dot ensemble²⁰—is instead related linearly to the bandgap of the ensemble constituents. In this regime, the V_{OC} for a given bandgap can be increased by the judicious addition of a larger bandgap species that modifies the density of states. The inventors have herein exploited this phenomenon and design CQD multi-bandgap ensembles that, by virtue of a tailored density of states and by spectrally matching the IR solar spectrum, simultaneously attain for the first time high V_{OC} and high J_{SC} of 0.4 V and 3.7±0.2 mA cm⁻², respectively, more than 30% higher than previously reported values for both parameters. As a result, the inventors have achieve cSi-filtered PCE of 1%—a record in infrared CQD PV.

### Results

### V_{OC} Modulation in Multi-Bandgap Quantum Dot Ensembles

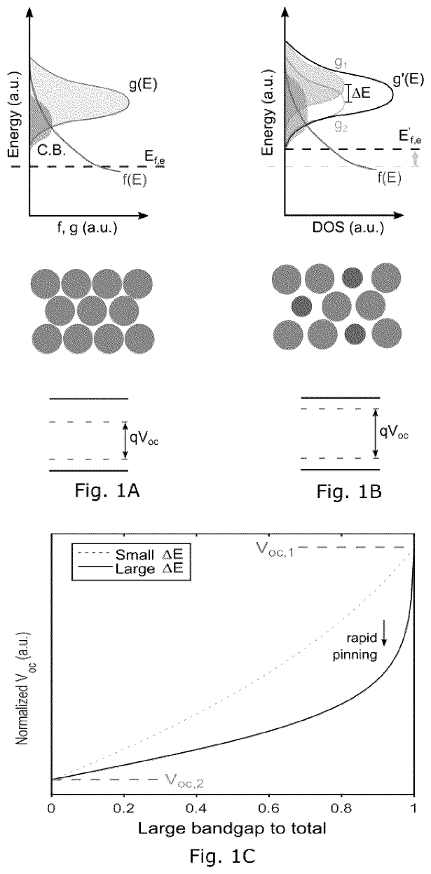

Under illumination, the electron quasi-Fermi level increase in solar cells made from a single population of CQDs is dictated by the excited carrier density that can be sustained in the conduction band in steady state. The overlap of the Fermi-Dirac occupation function at the quasi-Fermi level ƒ(E, E_{QFL}) and the density of states (DOS) at the CQD conduction g_{CB}(E) band determines this photoexcited electron density (FIG. 1A):

Δn=∫_{E}_{_{c}}^{∞}ƒ(E,E_{QFL})g_{CB}(E)dE (1)

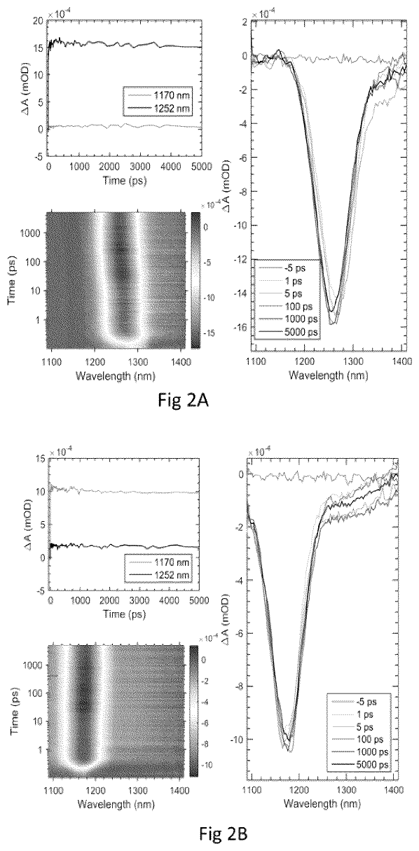

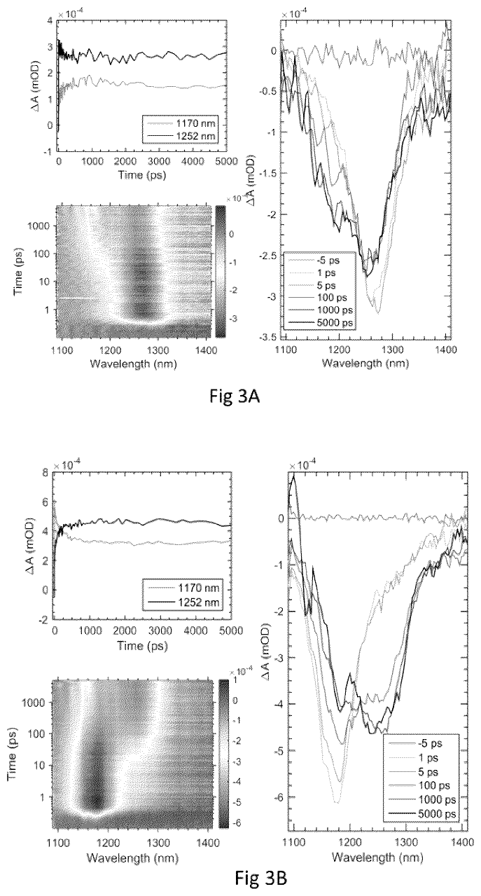

A similar expression holds for photoexcited holes in the valence band. Mixing different CQD ensembles can be used to modify proportionately the effective DOS, which affects the overlap with the Femi-Dirac distribution of electrons depending on the relative weight of the populations and the difference in energy ΔE of the mixed dot ensembles (FIG. 1B). For a given photoexcited charge density Δn, E_{QFL} will therefore increase if the relative density of lower energy states is reduced. We note that the F-D distribution is appropriate to describe the occupation probability not only in bands, but also of discrete energy states—such as, for example, in the monoatomic ideal gas, and, more broadly, in systems with single-particle energy levels. Fermi-Dirac statistics apply only if the particles in the system can reach thermal equilibrium. Using ultrafast transient absorption spectroscopy, see FIGS. 2 and 3 it was verified experimentally that, in the pure and mixed CQD mixes, photoexcited electrons and holes²³ thermalize to the nearby available states in a few nanoseconds, well before they are lost to recombination, and thus do reach thermal equilibrium within their band.

To quantify this effect, we employed a band-filling model and calculated the impact of CQD size mixing on V_{OC}. The conduction and valence DOS were built assuming Gaussian CQD size distributions and using the following size-to-bandgap relation:

$${E}_{G} = \frac{1}{0.0252 {x}^{2} + 0.283 x} , \qquad ( 2 )$$

where E_{G} is the bandgap in electron volts (eV) and x, the quantum dot diameter (nm). To retrieve the quasi-Fermi level splitting, which corresponds to the upper V_{OC} limit, the steady state photoexcited charge generation rate is set equal to the recombination rate, which is assumed to be dominated by mid-gap tail states. Details and calculation parameters are as follows.

### V_{OC} Calculation Details and Parameters

The calculation of V_{OC} is based on the detailed balance procedure as described in¹. When setting the photoexcited charge carrier generation rate G equal to the recombination rate through mid-gap trap states, one can obtain the following equation:

$$G = \frac{{n}_{i} \{ exp [ ( {ɛ}_{FC} - {ɛ}_{FV} ) / k T ] - 1 \}}{\begin{matrix}{τ}_{h , min} \{ exp [ ( {ɛ}_{FC} - {ɛ}_{i} ) / k T ] + exp [ ( {ɛ}_{imp} - {ɛ}_{i} ) / k T ] \} + \\ {τ}_{e , min} \{ exp [ ( {ɛ}_{i} - {ɛ}_{FV} ) / k T ] + exp [ ( {ɛ}_{i} - {ɛ}_{imp} ) / k T ] \}\end{matrix}} , \qquad ( 3 )$$

where nᵢ is the intrinsic carrier density, ε_{FC} and ε_{FV} are the electron and hole quasi-fermi levels in the conduction and valence band, k is Boltzmann's constant, T is temperature, τ_{h,min} and τ_{e,min} are the minimum hole and electron lifetime, εᵢ is the intrinsic fermi level and εᵢₘₚ, the trap energy level. Assuming symmetric properties for holes and electrons for simplicity, this expression reduces to

$$G = \frac{{n}_{i} \{ exp [ ( {ɛ}_{F C} - {ɛ}_{FV} ) / k T ] - 1 \}}{2 {τ}_{min} \{ exp [ ( {ɛ}_{FC} - {ɛ}_{FV} ) / 2 k T ] + cosh [ ( {ɛ}_{imp} - {ɛ}_{i} ) / k T ] \}} , \qquad ( 4 )$$

which reduces further in the case of mid-gap traps (εᵢₘₚ=εᵢ) to

$$G = \frac{{n}_{i} \{ exp [ ( {ɛ}_{F C} - {ɛ}_{F V} ) / k T ] - 1 \}}{2 {τ}_{min} \{ exp [ ( {ɛ}_{FC} - {ɛ}_{FV} ) / 2 k T ] + 1 \}} \approx \frac{{n}_{i} \{ exp [ ( {ɛ}_{FC} - {ɛ}_{F V} ) / 2 k T ] \}}{2 {τ}_{min}} . \qquad ( 5 )$$

Knowing all other parameters, this can then be numerically solved to find the quasi-fermi level splitting, ε_{FC}−E_{FV}.

The carrier lifetime τ is calculated from the trap density N_{T}, thermal velocity vₜₕ and capture cross-section s, as

$$τ = \frac{1}{{N}_{T} {v}_{th} s} , \qquad ( 6 )$$

where s is approximated as the cross-section of a quantum dot and vₜₕ, defined in the hopping regime as d/τₕₒₚ, is obtained from the mobility:

$${v}_{t h} = \frac{6 k T μ}{d} . \qquad ( 7 )$$

The carrier generation rate G is calculated from the absorption coefficient α(λ) and the incident photon flux γ(λ) (corresponding to the IR-filtered AM1.5G solar spectrum divided by hc/λ):

G=∫_{1100 nm}^{∞}α(λ)γ(λ)dλ. (8)

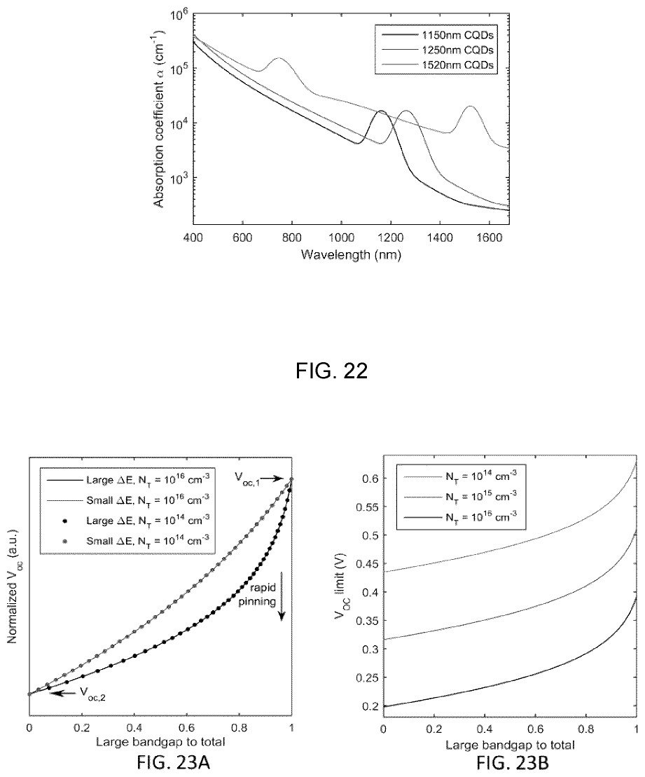

The absorption coefficients α(λ) used in the calculation are shown in FIG. 22.

To calculate nᵢ, we first build the conduction band DOS, g_{CB}(E):

$${g}_{C B} ( E ) \approx \frac{δ P}{{V}_{e x c}} \frac{1}{\sqrt{2 π {σ}^{2}}} exp ( - \frac{{( E - {E}_{exc} )}^{2}}{2 {σ}^{2}} ) , \qquad ( 9 )$$

where δ is the degeneracy of the lowest energy state, P is the dot packing density, V_{exc} is the average volume of a dot, E_{exc} is the average lowest energy state (equal to the first excitonic peak position in the absorption spectrum) and a is the standard deviation of the distribution. V_{exc} is calculated by approximating the dots as spheres. The central position and FWHM of the exciton peak in the CQD films absorption spectra were used to extract the parameters of the gaussian distribution. Assuming the fermi level lies approximately in the middle of the bandgap, nᵢ can then be evaluated:

nᵢ=∫_{E}_{_{c}}^{∞}ƒ(E)g_{CB}(E)dE, (10)

where ƒ(E) is the Fermi-Dirac distribution. Finally, the QD diameter d is obtained from equation (2) given in the main text. In the case of a mix of two CQD populations with a different mean size and mixing proportion x, the effective DOS is estimated to be a weighted sum of both populations' DOS:

g_{CB,total}(E)=xg_{CB,1}+(1−x)g_{CB,2}. (11)

The trap density was kept constant in the calculation in order to isolate the effects of CQD mixing only on V_{OC} pinning, see FIG. 23A illustrates that the trend in V_{OC} pinning remains identical for different trap densities, while only the magnitude of V_{OC} is affected, as shown in FIG. 23B.

The numerical values used in the calculations are given in Table 1 below.

TABLE 1
Numerical values used in V_{oc} calculation.

| | | Small ΔE | | Large ΔE | |
|---|---|---|---|---|---|
| QD bandgap | E_{exc} | 1.08 eV, 1.00 eV | | 1.08 eV, 0.82 eV | |
| | | (1150 nm, 1250 nm) | | (1150 nm, 1520 nm) | |
| QD diameter | d | 3.9 nm, 4.4 nm | | 3.9 nm, 5.7 nm | |
| QD size | σ | 40 meV (4% size | | 40 meV (4% size | |
| distribution | | dispersity) | | dispersity) | |
| standard | | | | | |
| deviation | | | | | |
| Temperature | T | 300 | K. | 300 | K. |
| QD packing | P | 0.65 | | 0.65 | |
| density | | | | | |
| Lowest-energy | δ | 8 | | 8 | |
| excited state | | | | | |
| degeneracy | | | | | |
| Trap density | N_{T} | 10¹⁶ | cm⁻³ | 10¹⁶ | cm⁻³ |
| Charge mobility | μ | 0.02 | cm²V⁻¹s⁻¹ | 0.02 | cm²V⁻¹s⁻¹ |

| | | | |
|---|---|---|---|
| Excited carrier | τ | 480 ns, 435 ns | 480 ns, 330 ns |
| lifetime | | | |
| Photogeneration | G | 3.7 × 10²⁰ cm⁻³s⁻¹, | 3.7 × 10²⁰ cm⁻³s⁻¹, |
| rate | | 5.2 × 10²⁰ cm⁻³s⁻¹ | 1.1 × 10²¹ cm⁻³s⁻¹ |

Different regimes are identified in the V_{OC} behavior upon CQD mixing (FIG. 1C) as a function of the energy offset. When ΔE is large compared to the FWHM of the DOS (given by the size distribution), the open-circuit voltage is rapidly pinned to the V_{OC} of the smallest-bandgap population. This case represents the conventional scenario in which, in a CQD film, the presence of narrow bandgap outliers and deep tail states dramatically reduces V_{OC}. As ΔE diminishes and the broadened DOS overlaps progressively more with ƒ(E), the open-circuit voltage shows an almost linear dependence on the V_{OC} corresponding to the individual populations of the CQD ensemble. We therefore predict that modifying the DOS by mixing in CQDs with a slightly higher bandgap should have an appreciable beneficial effect on V_{OC}.

### Transport Characteristics of Multi-Bandgap CQD Ensembles

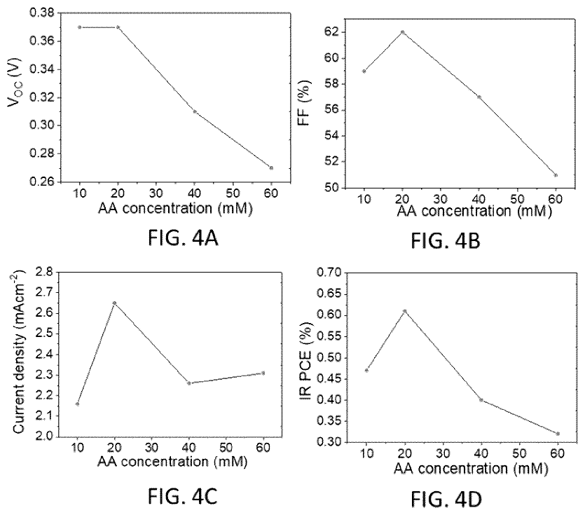

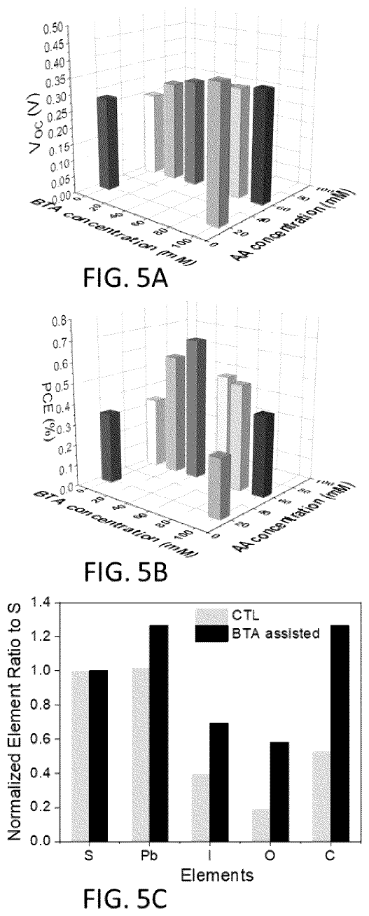

The inventors then proceeded to make films of CQD ensembles based on a solution-phase exchange method to replace the as-synthesized oleic acid capped CQDs with short inorganic halide ligands. Our solution exchange is based on a previously-reported protocol^{[2]} for 1150 nm (large bandgap, L) and 1250 nm (small bandgap, S) CQDs. We optimized the solution exchange protocol as follows:^{[2]} for 1150 nm CQDs, we kept PbI₂ and Pb(SCN)₂ at the same concentration as our previous work and modified the concentration of ammonium acetate (AA) from 10 mM to 60 mM in dimethylformamide (DMF), see FIGS. 4A to 4D. When we increase the AA concentration, V_{OC} decreases while FF and PCE increase before decreasing as well, which is ascribed to surface passivation and change in residual OA on the surface. The optimal concentration of AA of 20 mM was found for the 1150 nm CQD ligand exchange. We also optimized the 1250 nm CQD ligand exchange, (see FIGS. 5A to 5C) by adjusting the AA concentration and added butylamine (BTA) to assist ligand exchange. In this case, the optimal concentration was found experimentally to be 60 mM for AA and 40 mM for BTA. We additionally performed X-ray photoelectron spectroscopy (XPS) to study the surface passivation (FIG. 5C). The addition of BTA allows for more organics (oleic acid) and iodide ions to remain on the CQD surface, as indicated by the higher ratio of I:S and C:S compared to the control ligand exchange without BTA. We finally mixed the individual solutions (with the choice of ratio explored throughout this work) prior to CQD film formation.

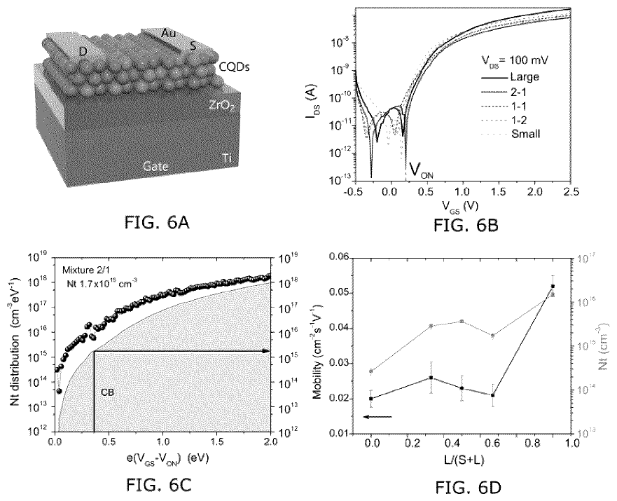

To characterize the charge mobility and density of tail states for different quantum dot ensembles, the inventors carried out field-effect transistor (FET) measurements (FIGS. 6A to 6D). We employed a bottom-gate top-contact configuration (FIG. 6A). The FET transfer characteristics for all the studied mixtures reveal the characteristic n-type character of halide-treated CQD films (FIG. 6B).

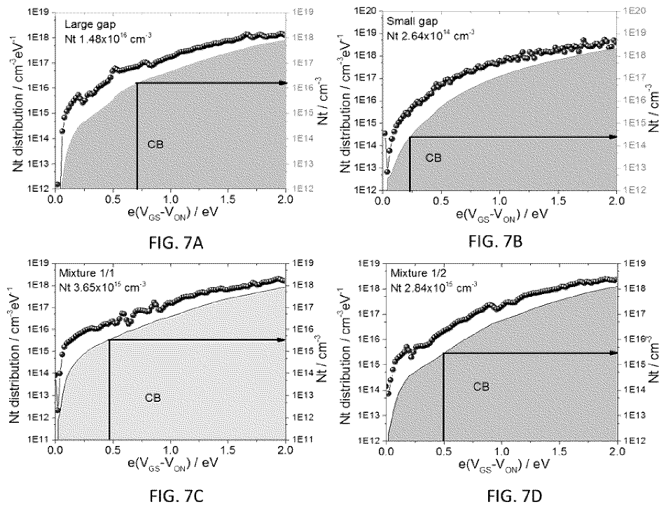

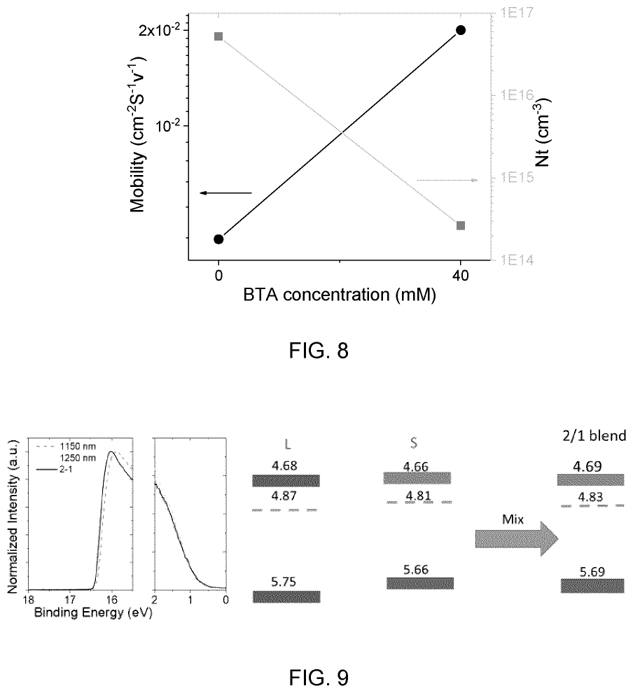

The inventors retrieved the density of in-gap states from the measured transfer characteristics. By analyzing the exponential increase of the drain current below V_{TH}, which corresponds to transport through in-gap states, we obtain the density of in-gap states. The tail state distribution is calculated using the following equation:

$${N}_{t d} = {[ ( \frac{S \cdot e}{kT \cdot ln ( 10 )} - 1 ) \cdot \frac{{C}_{i}}{e} ]}^{2} \cdot {ϵ}_{0} {ϵ}_{r}^{- 1} \qquad ( 12 )$$

where S is the sub-threshold swing, the slope of the gate voltage versus the log drain current between turn-on voltage and V_{TH} that defines the boundary between the subthreshold and transport regime; ϵ₀ is the vacuum permittivity; ϵᵣ is the electric constant of the film, estimated to be 10.9. After integrating the tail state distribution between the subthreshold and transport regime as shown in FIG. 6C for the mixture (weight ratio of 2 to 1), we obtain the density of tail states (N_{T}) (see FIGS. 7A to 7D) plotted in FIG. 6D, grey square. The pure large gap CQD film exhibits a N_{T} of 1.5±0.2×10¹⁶ cm⁻³ (see FIG. 7A), which is close to that of solution exchanged 950 nm PbS CQDs. The pure small-gap CQD film shows a two orders of magnitude lower N_{T} of 2.6±0.5×10¹⁴ cm⁻³ compared to the pure large gap CQD film (FIG. 7A, 7B), a finding we ascribe to better surface passivation. We also compared the transport properties of small bandgap dots exchanged with and without the BTA additive (see FIG. 8). The CQD film exchanged without BTA exhibits a N_{T} of 5.2±0.4×10¹⁶ cm⁻³, while the addition of BTA lead to a much lower N_{T} of 2.6±0.5×10¹⁴ cm⁻³, again due to better surface passivation. The CQD mixtures containing 33%, 50%, and 67% of large bandgap CQDs exhibit a N_{T} of 2.8±0.4×10¹⁵, 3.6±0.3×10¹⁵, and 1.7±0.3×10¹⁵ cm⁻³, respectively, an order of magnitude lower than that of the pure large gap CQDs, indicating that the mixtures should have similar or even better carrier transport compared to the large bandgap CQD films.

In addition to obtaining tail density, we also extracted charge carrier mobility from FET measurements (FIG. 6D, black square). The carrier mobility is calculated from the slope of I_{DS} versus V_{GS} according to the equation I_{DS}=μCᵢW/L(V_{GS}−V_{TH})V_{DS}, where μ is the carrier mobility in the linear regime; I_{DS} is the drain current; L and Ware the channel length (50 μm) and channel width (2.5 mm) respectively; and V_{GS} and V_{TH} are the gate voltage and threshold voltage, respectively. The pure large-gap CQD film has an electron mobility of 0.052±0.003 cm²V⁻¹s⁻¹, while the pure small-gap CQD film shows a lower mobility of 0.020±0.002 cm²V⁻¹s⁻¹, which may be due to the residual oleic acid ligands on the CQD surface. The CQD films with inclusions of large bandgap CQDs of 33%, 50%, and 67% exhibit mobilities of 0.026±0.004, 0.023±0.004, and 0.021±0.003 cm²V⁻¹s⁻¹, respectively. In addition, we studied charge carrier transport between the two differently-sized distributions using ultrafast transient absorption spectroscopy (FIGS. 2A, 2B and 3A and 3B). We found that the wide size dispersity allows for photoexcited charges to be thermally excited into larger and/or smaller dots, thereby thermalizing into the nearby available states in a few nanoseconds. We also conducted ultraviolet photoelectron spectroscopy (UPS) (FIG. 9) to determine the position of the energy levels of the single size CQDs, and confirmed that they have energy levels needed for band alignment.

### Tailoring the Multi-Bandgap CQD Ensembles Spectral Response

The band-filling model and FET analysis indicate that the mixtures can achieve improved V_{OC} and comparable charge transport properties. We sought to leverage this property and turned our attention to the optical behavior of the multi-bandgap CQD ensemble and aimed to maximize the overlap of light absorption with the cSi-filtered infrared solar spectrum.

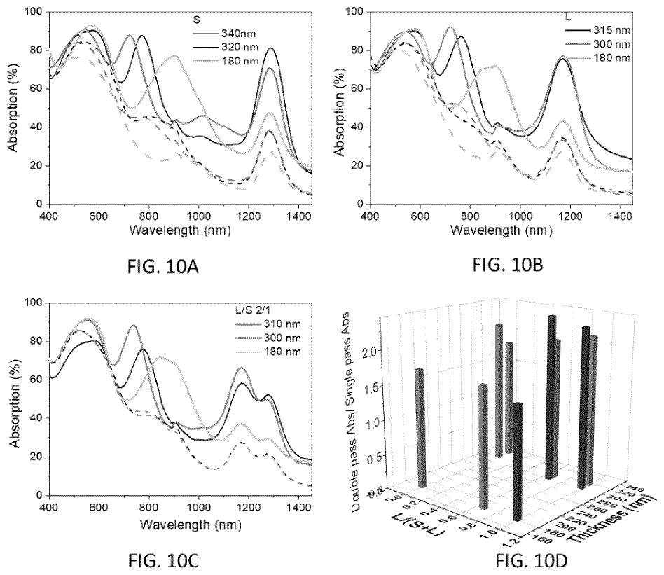

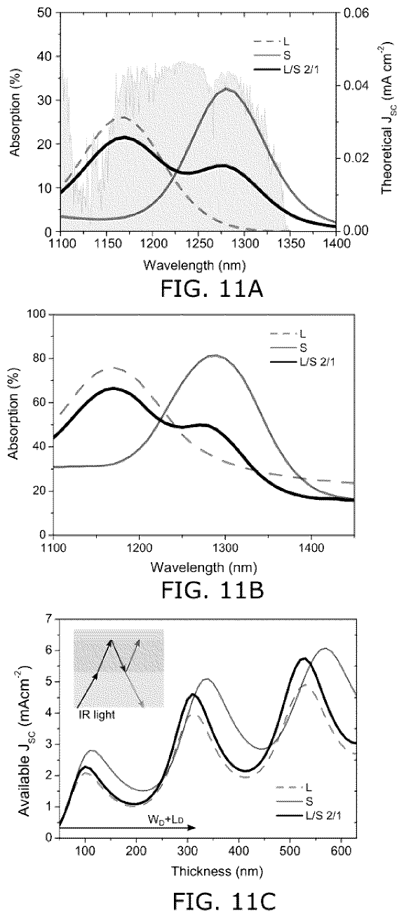

FIG. 11A shows the single pass absorptance of CQD films of the same thickness (300±10 nm) on optical glasses, where the 2:1 (large bandgap:small gap) films have a lower absorptance maxima than pure CQDs (around 30%). The mixtures do not show significantly higher IR photon absorption than the pure CQD films. In a complete CQD solar cell, however, the gold back-electrode serves also as a mirror. The resulting reflection contributes to the device absorptance and introduces resonant absorption. This is due to interference between the forward-propagating light from the illuminated side and the backward-propagating light reflected on the gold electrode and can be controlled and optimized by adjusting the active layer thickness. We thus measured the total absorption through complete PV devices (FIG. 11B). We observed that light absorption in the mixtures is enhanced at certain wavelengths, which contribute to additional photo-generated current. To confirm the effect of optical resonance, we additionally measured light absorption in CQD films before Au deposition (see FIGS. 10A to 10D), which lack the resonant absorption peaks present in the absorption spectra of devices containing the Au back mirror, thus confirming the role of the resonant mechanism.

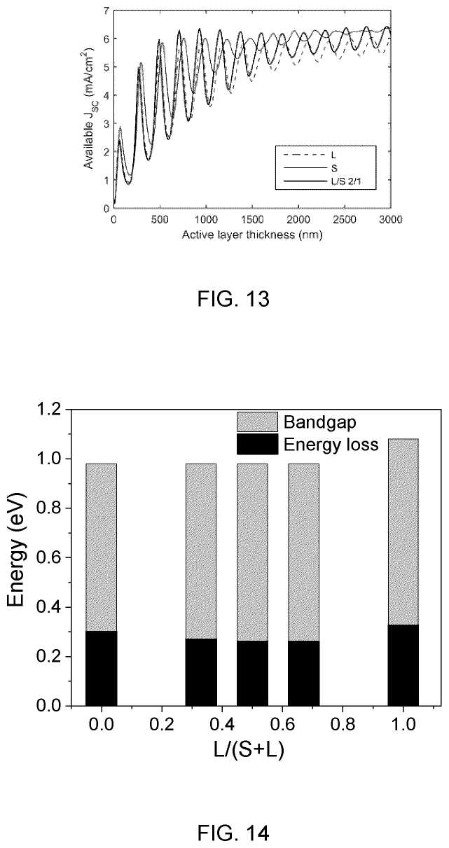

To optimize the total IR absorption, we calculated the available J_{SC} as the thickness of the active layer varies using the transfer-matrix method (FIG. 11C and FIG. 13). Pure large bandgap dots and 2 to 1 mixture films have a local J_{SC} maximum at a thickness of about 300 nm, while the pure small bandgap dots can absorb more light at about 340 nm, which is due to the absorption peak position difference. The available J_{SC} decreases after the first local maximum, and much thicker CQD films (above 500 nm) are required for a net increase in J_{SC}. For such a large thickness, the efficiency of charge carrier extraction will be dramatically reduced, as the diffusion length in these CQD solids is in the order of hundreds of nm. Based on these findings, we narrowed our attention to 2 to 1 mixtures and active layer thicknesses ranging from 200 to 350 nm.

### PV Device Performance

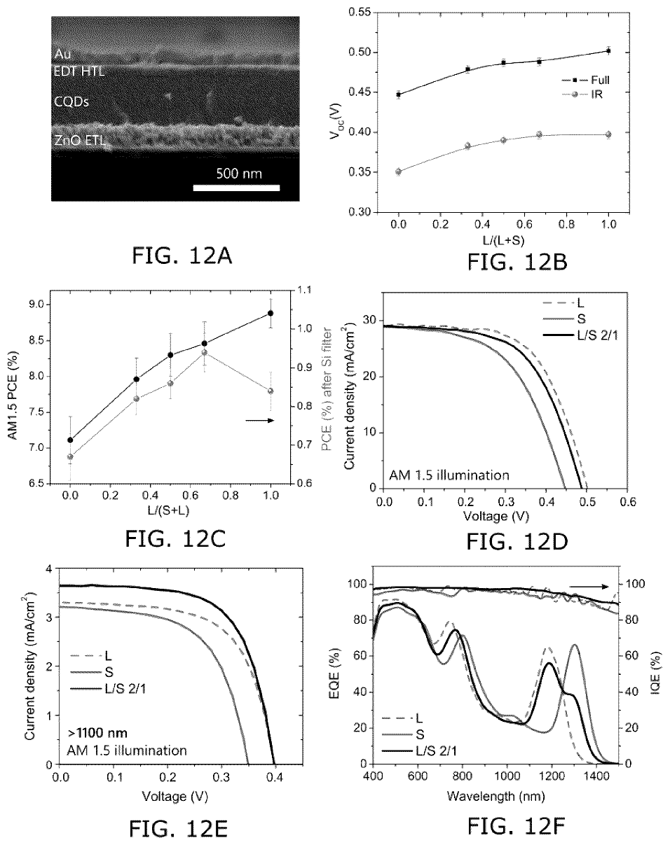

The inventors characterized the photovoltaic performance of solar cells employing multi-bandgap CQD ensembles (FIGS. 12A to 12F). FIG. 12A shows the PV Device architecture and cross-sectional SEM image of the best mixed CQD film solar cell. The performance is shown in FIGS. 12B to 12F in which FIG. 12B shows V_{OC} and FIG. 12C shows PCE with the different inclusion of large bandgap CQDs. FIG. 12D shows the J-V characteristics under AM1.5G, FIG. 12E shows the J-V characteristics after 1100 nm, and FIG. 12F shows the AM1.5G EQE curves and IQE curves of optimal single and mixed CQD solar cell devices.

More particularly, the devices where comprised of a ZnO layer, acting as an electron acceptor; an active layer formed of PbS CQD ensemble; EDT-exchanged PbS CQDs as the hole acceptor, and thermally evaporated gold as the top electrode, an scanning electron micrograph (SEM) of the structure being shown in FIG. 12A.

The open-circuit voltage shows the predicted trend upon quantum dot mixing (FIG. 12B). The AM1.5 V_{OC} for large bandgap is 0.50 V, and 0.45 V for small bandgap CQDs. The V_{OC} of 0.45 V for small-gap CQDs is higher than previous reports for similar sizes (0.38 V), which we ascribe to the lower N_{T} stemming from better passivation. The V_{OC} of mixtures gradually shifts between the two pure CQDs, relating to the weight inclusions almost linearly as expected from the state-filling model. We calculated the energy loss dependence on the inclusion of large bandgap CQDs in mixed CQD films under AM1.5 irradiation (see FIG. 14) and found that the mixed CQDs exhibit the lowest Eₗₒₛₛ (less than 0.27 eV), lower than that of the large and small bandgap CQDs (0.33 and 0.30 eV, respectively).

The inventors characterized the PV devices after an 1100 nm long-pass filter to replicate the effect of a silicon front cell. The mixture with 67% of large bandgap CQDs shows an IR V_{OC} of 0.40 V, similar to that of pure large bandgap CQDs films. This further demonstrates the benefit of multi-bandgap CQD ensembles to maximize open-circuit voltage. With fewer inclusions of large-gap CQDs, the IR V_{OC} of the mixtures gradually decreases with the decreased portion of large-gap CQDs. The similar IR V_{OC} of mixed CQD films compared to pure large bandgap CQD films can be attributed to the lower N_{T} than that of pure large bandgap CQD films, which reduces trap-assisted recombination, lowering the drop of V_{OC} with the reduced light intensity. The ideality factor (FIG. 21B) extracted from dark IV (FIG. 21A) dark IV shows that the small bandgap CQDs and mixed films have slightly smaller value than that of the large bandgap CQD films in the quasi-flat region. This is an indication of a higher density of trap states in large bandgap CQDs, in good agreement with the FET data. The ideality factor increasing above two (2) at higher voltages is due to series resistance.

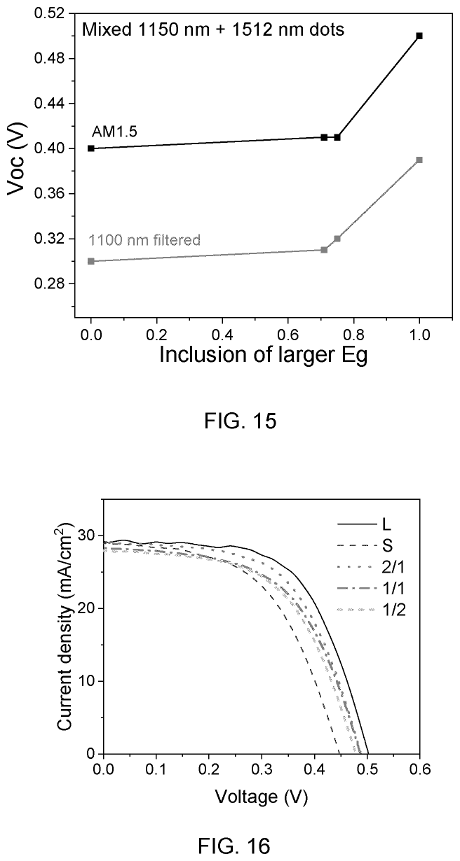

The inventors investigated the impact of a higher bandgap difference between the mixed CQDs on the resulting V_{OC} (see FIG. 15). The V_{OC} of mixes of CQDs with exciton peaks at 1150 nm and 1512 nm quickly decreases to the value close to the small bandgap CQDs, in agreement with the theoretical model.

Multibandgap CQD ensembles exhibit a superior IR PCE compared to pure CQD films (see FIG. 12C, and Table 2 below).

TABLE 2
Spectral mismatch factor calculated
from the EQE spectrum of each device.

| | Spectral |
|---|---|
| | mismatch |
| Device | factor |
| S | 2.04 |
| L | 1.82 |
| L/S 2/1 | 1.86 |
| L/S 1/1 | 1.8 |
| L/S 1/2 | 1.83 |

The best IR PCE of 0.95±0.04% was obtained in the mixture containing 67% large bandgap CQDs, with a 0.40±0.01 V V_{OC}, 3.7±0.2 mA cm⁻² J_{SC}, and a 65±1% fill factor (FF). The best large-bandgap CQD films, on the other hand, led to a PCE of 0.84±0.03% with V_{OC}, J_{SC}, and FF at 0.40±0.01 V, 3.3±0.2 mA cm⁻², 64±1%, the small bandgap CQD solar cells yielded a PCE of 0.67±0.05% with V_{OC}, J_{SC}, and FF at 0.35 V, 3.2±0.2 mA cm⁻², 60±1%. The device performance under unfiltered AM1.5G illumination is presented in FIG. 16 and Table 3 for reference.

TABLE 3
Performance summary of optimal solar cells under AM1.5 irradiation and
IR performance >1100 nm at optimal thickness from more than 10 devices.

| | | Large gap CQD fraction | | | | |
|---|---|---|---|---|---|---|
| | | 0 | 33% | 50% | 67% | 100% |
| AM1.5G | Thickness | 320 nm | 300 nm | 300 nm | 300 nm | 300 nm |
| performance | V_{OC} (V) | 0.45 ± 0.005 | 0.47 ± 0.005 | 0.48 ± 0.005 | 0.49 ± 0.005 | 0.50 ± 0.005 |
| at optimal | J_{SC} (mA cm⁻²) | 29 ± 0.5 | 28 ± 0.5 | 28.3 ± 0.5 | 29.4 ± 0.5 | 29 ± 0.5 |
| thickness | FF(%) | 54 ± 1 | 60 ± 1 | 61 ± 1 | 59 ± 1 | 61 ± 1 |
| | PCE (%) | 7.0 ± 0.3 | 8.0 ± 0.3 | 8.3 ± 0.3 | 8.5 ± 0.3 | 8.9 ± 0.2 |
| IR | Thickness | 320 nm | 310 nm | 310 nm | 300 nm | 300 nm |
| performance | V_{OC} (V) | 0.35 ± 0.005 | 0.38 ± 0.005 | 0.39 ± 0.005 | 0.40 ± 0.005 | 0.40 ± 0.005 |
| at optimal | J_{SC} (mA cm⁻²) | 3.2 ± 0.2 | 3.4 ± 0.2 | 3.4 ± 0.2 | 3.7 ± 0.3 | 3.3 ± 0.2 |
| thickness | FF(%) | 60 ± 1 | 63 ± 1 | 64 ± 1 | 65 ± 1 | 64 ± 1 |
| | PCE (%) | 0.67 ± 0.06 | 0.82 ± 0.04 | 0.86 ± 0.04 | 0.94 ± 0.05 | 0.84 ± 0.05 |

The inventors tested three different multi-bandgap CQD ensemble configurations, containing large bandgap CQDs from 33% to 67%; all these three compositions showed at least 20% improvement compared to the small bandgap samples. The enhancement of absorption in mixtures containing 67% large-bandgap CQDs yields an enhanced J_{SC} of 3.7 mA cm⁻², calculated from the EQE:

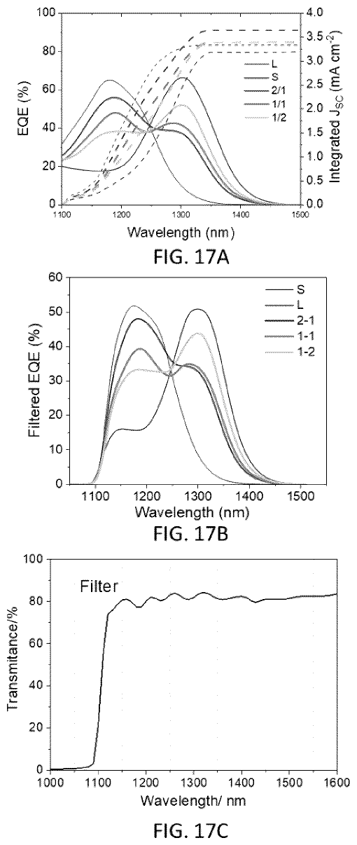

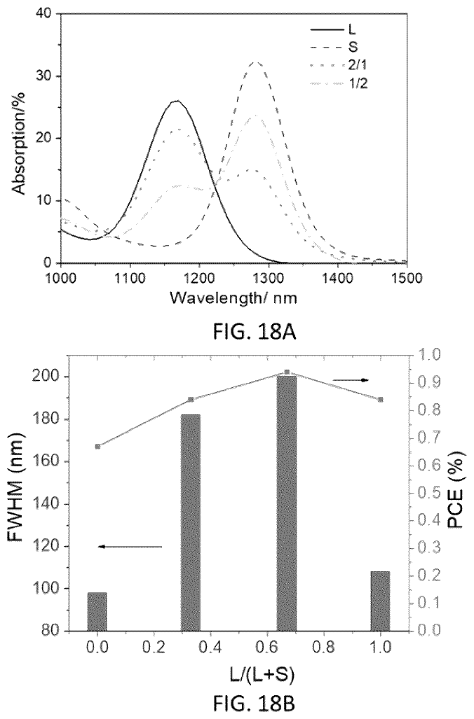

J_{sc}=q∫₀^{∞}EQE(λ)γᵢ(λ)dλ

where γᵢ(λ) is the incident solar photon flux spectrum. Tailoring the absorption spectrum leads to this increase in J_{SC} by better matching the external quantum efficiency (EQE) spectrum to the solar spectrum over the 1100 nm to 1400 nm spectral range (see FIG. 17A). The EQE of the best mixed CQD device is wider than its pure counterparts, as seen by the increase in full-width half-maximum (FWHM) of the exciton peak (see FIGS. 18A and 18B), which in turn leads to an increase in photocurrent when the absorption spectrum is well matched to the solar spectrum. The shape of the exciton peak and its FWHM was tuned to the solar spectrum to increase J_{SC} while minimizing V_{OC} loss. We note that the extended FWHM of the exciton peak did not improve J_{SC} under full-AM1.5-spectrum one-sun conditions (FIG. 12D and FIG. 16) because optical resonances improve in some spectral regions, but decrease in others, the absorbance.

The inventors calculated the internal quantum efficiency IQE using the measured EQE and simulated light absorption in the CQD active layer (FIG. 12F). Multibandgap CQD ensembles show enhanced EQE and IQE compared to pure CQD films, as transport of photogenerated charges takes place mainly through low defect-density, small-bandgap CQD paths. The enhanced EQE in multi-bandgap CQD ensembles shows not only the improved spectral range from the extended absorption, but also the enhanced transport, higher than pure CQD films, as was demonstrated by FET results.

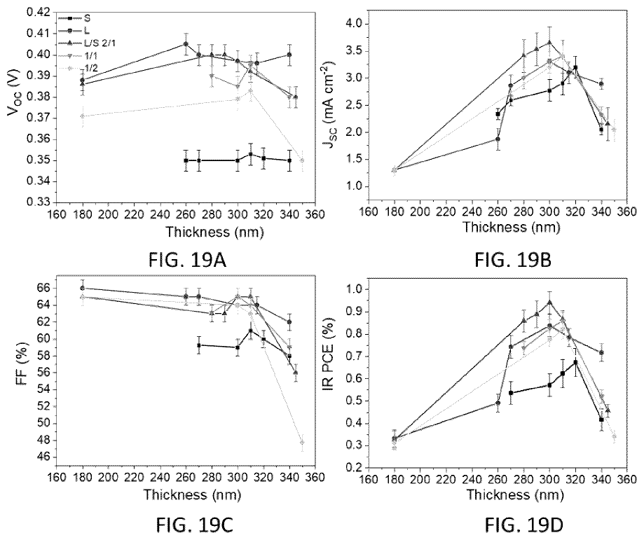

The inventors investigated the thickness-dependent performance of the pure and mixed CQD films (see FIGS. 19A to 19D) The optimal thickness for every device is found to be around 300 nm, where J_{SC} decreases as the thickness increases due to resonant absorption as discussed above, which is in good agreement with the double pass absorption and simulation in FIGS. 11A to 11C and FIG. 10. For different inclusions of L, the 67% of L CQDs yields the highest J_{SC} of 3.7 mA cm⁻² at a thickness of 300 nm, whereas the 50% and 33% of L CQDs both yield the highest J_{SC} of 3.4 cm⁻² when they are 320 nm thick.

In this disclosure, the inventors disclose a strategy based on multi-bandgap CQD ensembles to achieve high open-circuit voltage, short-circuit current and PCE in cSi-filtered IR photovoltaics. The inventors have engineered the density of states in this platform to improve quasi-Fermi level splitting and increase V_{OC}. The inventors further leveraged the optical properties of multi-bandgap CQD ensembles to achieve solar-matched IR light absorption, leading to high J_{SC} and a record cSi-filtered power conversion efficiency of 1%, setting a record for silicon-filtered CQD PVs. This strategy, which allows decoupling of the traditional V_{OC}-J_{SC} trade-off, has the potential to raise the IR PCE in the direction of the 6% theoretical limit with the improved light absorption properties of a mixture of CQD populations well-matched to the solar spectrum.

In conclusion, the inventors have developed a novel strategy to realize multispectral solar energy harvesting photovoltaic devices using solution-processed semiconductor materials. This strategy is based on the use of ensembles of semiconductor nanocrystals (NC) with different bandgaps that are first individually pre-synthesized in solution and then mixed and assembled to form a composite semiconducting solid film. The resulting composite can be tailored to absorb at different wavelength regions by changing the individual nanocrystal populations and their relative concentration as well as their bandgaps.

The composite exhibits a tunable joint density of states (JDOS) where the quasi-Fermi level splitting can be larger than that achievable in films only consisting of the smallest bandgap population. The JDOS can be tuned by modifying the nanocomposite constituents, their relative content and their assembly.

These photovoltaic devices very surprisingly exhibit an open-circuit voltage that is not pinned to that attainable in a device employing a single population of small bandgap nanocrystals but follows the JDOS of the composite. The open-circuit voltage can be proportional to the weighted average of the bandgaps of the individual nanocrystals. The open-circuit voltage can be tuned by modifying the nanocomposite constituents and their relative content to vary the open circuit photovoltage between the photovoltage exhibited by a device with only one set of quantum dots with the smaller bandgap and the photovoltage exhibited by a device Zo only one set of quantum dots with the larger bandgap.

The original nanocrystal solutions consist of nanocrystals with different bandgaps that can also possess a different doping and a different surface functionalization. The different nanocrystal solutions can be subjected to various surface modifications such as solution exchanges before their mixture and assembly.

These photovoltaic nanocomposites exhibit a tunable joint density of states arising from the equilibration of the density of states of different populations of the nanocrystals once they are assembled in a solid film.

A photovoltaic nanocomposite device is provided that compromises different bandgap semiconductor nanocrystals embedded in a host semiconductor matrix such as an organic semiconductor, a perovskite matrix, or an inorganic nanocrystal matrix. Such a matrix can have different roles, such as: directing nanocomposite self-assembly; retaining nanocrystal monodisperisty; improving the surface passivation of the embedded nanocrystals; facilitating charge and energy transfer within the nanocrystal ensemble; and improving open-circuit voltage further. As a non-limiting example, the host matrix in the photovoltaic nanocomposite can be a metal halide perovskite such as an organic-inorganic perovskite, a layered-perovskite or an oxide or sulfide perovskite.

The present disclosure provides a nanocomposite compromising nanocrystals of different bandgap embedded in the aforementioned matrix, wherein the matrix presents a weight percentage of 1 to 99%.

A photovoltaic device that employs the aforementioned nanocrystal-ensemble-in-a-matrix composite sandwiched between an electron blocking layer and a hole blocking layer.

### REFERENCES

[1] X. Lan, O. Voznyy, A. Kiani, F. P. G. de Arguer, A. S. Abbas, G.-H. Kim, M. Liu, Z. Yang, G. Walters, J. Xu, M. Yuan, Z. Ning, F. Fan, P. Kanjanaboos, I. Kramer, D. Zhitomirsky, P. Lee, A. Perelgut, S. Hoogland, E. H. Sargent, Adv. Mater. 2016, 28, 299.
[2] B. Sun, O. Voznyy, H. Tan, P. Stadler, M. Liu, G. Walters, A. H. Proppe, M. Liu, J. Fan, T. Zhuang, J. Li, M. Wei, J. Xu, Y. Kim, S. Hoogland, E. H. Sargent, Adv Mater 2017, 29, 1700749.

1. A quantum dot based solar cell device, comprising:
a substrate;
a light harvesting structure sandwiched between electrically conducting layers, at least one electrically conducting layer being substantially transparent, said light harvesting structure being located on said substrate;
said light harvesting structure including a layer of semiconducting quantum dots, said layer of semiconducting quantum dots including at least two distinct sets of semiconducting quantum dots which are homogenously mixed, one of said two distinct sets of semiconducting quantum dots having a first bandgap and the at least one other distinct set of semiconducting quantum dots having a second bandgap different from said first bandgap, both sets of semiconducting quantum dots being passivated with any one or combination of halides and pseudo-halides; and
upon illumination, said quantum dot solar cell device exhibits a photovoltage that is intermediate between a photovoltage that would generated separately if said solar cell device had only the first set of quantum dots and a photovoltage that would be generated separately if said solar cell device had only the second set of quantum dots.

2. The solar cell device according to claim 1, wherein the offset of both the valence and conduction bands in the at least two different types of quantum dots have an offset by amounts being up to about 0.3 eV and the bandgap difference between the smallest bandgap value and the largest bandgap value in the quantum dot sets has an offset up to about 0.3 eV.

3. The solar cell device according to claim 1, wherein said at least two distinct sets of semiconducting quantum dots have the same chemical composition, but have different sizes such that each distinct set has a bandgap different from the other set.

4. The solar cell device according to claim 1, wherein each set of semiconducting quantum dots has a chemical composition different from the other sets.

5. The solar cell device according to claim 1, wherein an interparticle separation of quantum dots in said homogenous mixture is in a range from about 0.1 nm to about 1 nm.

6. The solar cell device according to claim 1, wherein said first set of quantum dots are present in the homogenous mixture in a range of about 1 to about 99 weight percent.

7. The solar cell device according to claim 1, wherein said semiconducting quantum dots are selected from the group consisting of Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS), InAs, InₓGa_{y}As_{z}, Ag₂S, Ag₂Se, ZnSe, SnS₂, and core-shell structures based on these quantum dots as the core.

8. The solar cell device according to claim 1, wherein said halide is any one or combination of chloride, bromide and iodide.

9. The solar cell device according to claim 1, wherein said pseudo halide is any one or combination of cyanide, cyanate, thiocyanate, isothiocyanate, selenocyanate and trinitromethanide.

10. The solar cell device according to claim 1, further comprising a hole transport layer sandwiched between said layer of semiconducting quantum dots and one of said electrodes on one side of said layer of semiconducting quantum dots and an electron transport layer semiconducting sandwiched between said layer of semiconducting quantum dots and the other electrode on the other side of said layer of semiconducting quantum dots.

11. The solar cell device according to claim 2, wherein said at least two distinct sets of semiconducting quantum dots have the same chemical composition, but have different sizes such that each distinct set has a bandgap different from the other set.

12. The solar cell device according to claim 2, wherein each set of semiconducting quantum dots has a chemical composition different from the other sets.

13. The solar cell device according to claim 2, wherein an interparticle separation of quantum dots in said homogenous mixture is in a range from about 0.1 nm to about 1 nm.

14. The solar cell device according to claim 2, wherein said first set of quantum dots are present in the homogenous mixture in a range of about 1 to about 99 weight percent.

15. The solar cell device according to claim 2, wherein said semiconducting quantum dots are selected from the group consisting of Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS), InAs, InₓGa_{y}As_{z}, Ag₂S, Ag₂Se, ZnSe, SnS₂, and core-shell structures based on these quantum dots as the core.

16. The solar cell device according to claim 2, wherein said halide is any one or combination of chloride, bromide and iodide.

17. The solar cell device according to claim 2, wherein said pseudo halide is any one or combination of cyanide, cyanate, thiocyanate, isothiocyanate, selenocyanate and trinitromethanide.

18. The solar cell device according to claim 2, further comprising a hole transport layer sandwiched between said layer of semiconducting quantum dots and one of said electrodes on one side of said layer of semiconducting quantum dots and an electron transport layer semiconducting sandwiched between said layer of semiconducting quantum dots and the other electrode on the other side of said layer of semiconducting quantum dots.

19. The solar cell device according to claim 3, wherein an interparticle separation of quantum dots in said homogenous mixture is in a range from about 0.1 nm to about 1 nm.

20. The solar cell device according to claim 3, wherein said first set of quantum dots are present in the homogenous mixture in a range of about 1 to about 99 weight percent.
